(19) United States
(12) Patent Application Publication
(10) Pub. No.: US 2009/0206900 A1
(43) Pub. Date: Aug. 20, 2009

(54) DUTY CYCLE CORRECTION CIRCUIT AND METHOD FOR CORRECTING DUTY CYCLE

(75) Inventors: Hee Woong Song, Ichon (KR); Yong Ju Kim, Ichon (KR); Sung Woo Han, Ichon (KR); Jae Min Jang, Ichon (KR); Hyung Soo Kim, Ichon (KR); Ji Wang Lee, Ichon (KR); Chang Kun Park, Ichon (KR); Ic Su Oh, Ichon (KR); Hae Rang Choi, Ichon (KR); Tae Jin Hwang, Ichon (KR)

Correspondence Address: BAKER & MCKENZIE LLP;PATENT DEPARTMENT, 2001 ROSS AVENUE, SUITE 2300, DALLAS, TX, 75201, US

(73) Assignee: HYNIX SEMICONDUCTOR, INC., Ichon (KR)

(21) Appl. No.: 12/168,560

(22) Filed: Jul. 7, 2008

(30) Foreign Application Priority Data
Feb. 14, 2008 (KR) 10-2008-0013454

(51) Int. Cl. H03K 3/017

(52) U.S. Cl. 327/175

(57) ABSTRACT

A duty cycle correction circuit capable of reducing current consumption and that includes a back-bias voltage supply circuit for supplying back-bias voltages, wherein a duty cycle of an input clock is reflected on the back-bias voltages; and a buffer for adjusting the duty cycle of the input clock and configured to receive the back-bias voltages.

### CROSS-REFERENCES TO RELATED APPLICATION

This application claims the benefit under 35 U.S.C. 119(a) of Korean Patent application No. 10-2008-0013454, filed on Feb. 14 2008, in the Korean Patent Office, the disclosure of which is incorporated herein by reference in its entirety as if set forth in full.

### BACKGROUND

1. Technical Field

The embodiments described herein relate to a semiconductor integrated circuit and, more particularly, to a duty cycle correction circuit and method for correcting duty cycle of a digital clock in a semiconductor integrated circuit.

2. Related Art

It is often important to exactly control the duty cycle of a digital clock signal used by a semiconductor integrated circuit. A digital clock signal with a duty cycle of 50% is commonly used in conventional digital clock circuits within conventional semiconductor integrated circuits. A duty cycle of 50% means that the clock signal is low for the same amount of time that it is high or active. That is, the duty cycle is a ratio of the active pulse width to the overall period of the clock signal.

A duty cycle correction circuit is used to generate a clock signal with a 50% duty cycle when a clock signal, which is not a 50%-duty-cycle signal, is received by, or input to the associated semiconductor integrated circuit.

Referring to FIG. 1, a conventional duty cycle correction circuit 11 often includes a first differential amplifier 10 and a second differential amplifier 20. In this example, the first differential amplifier 10 includes a first resistor R1, a second resistor R2, a first NMOS transistor N1, a second NMOS transistor N2 and a first current source CS1. The second differential amplifier 20 includes a third NMOS transistor N3, a fourth NMOS transistor N4 and a second current source CS2.

The first differential amplifier 10 buffers and amplifies a clock signal ‘clk’ and an inverted version of the clock signal ‘clkb’, and outputs an output signal ‘out’ and an inverted output signal ‘outb’. The second differential amplifier 20 receives a duty control signal ‘dcc’ and ‘dccb’ according to the duty cycle of the output signal ‘out’ and the inverted output signal ‘outb’ and corrects the duty cycle of the output signal ‘out’ and the inverted output signal ‘outb’ by adjusting voltages on first and second nodes Node1 and Node2 through which the output signal ‘out’ and the inverted output signal ‘outb’ are output respectively.

However, because the duty cycle correction circuit of FIG. 1 uses two differential amplifiers, each having a current source, the current consumption can be prohibitively high for certain applications and is generally increased due to the dual differential amplifiers.

### SUMMARY

A duty cycle correction circuit capable of reducing current consumption and a method for correcting the duty cycle of a digital clock signal are described herein.

According to one aspect, a back-bias voltage supply circuit configured to receive an output signal and to generate a back-bias voltage, wherein a duty cycle of an input clock signal is reflected on the back-bias voltage; and a buffer configured to receive the input clock signal and the back-bias voltage, to adjust the duty cycle of the input clock signal in response to the back-bias voltage, and to output the output signal based on the adjusted input clock signal.

According to another aspect, outputting a duty detection signal by detecting a duty cycle of an output signal; generating back-bias voltages in response to the duty detection signal; and receiving an input clock signal and generating the output signal by adjusting the duty cycle of the input clock signal according to the back-bias voltages.

According to still another aspect, a duty cycle correction circuit comprises a buffer comprising a first input unit configured to receive an input clock and a first back-bias voltage, the duty cycle of the input clock signal being reflected on the first back-bias voltage, a second input unit configured to receive a reference voltage, a current source unit coupled with the first input unit, and wherein the current source unit is further configured to provide a current flowing into the first input unit, and wherein the first input unit is further configured to vary an amount of current flowing through the first input unit according to the first back-bias voltage, a power supply voltage terminal, and a first load unit coupled with the power supply voltage terminal and the first input unit, the load unit configured to output an output signal, the DC voltage level of which is based on an amount of current flowing through the first input unit.

These and other features, aspects, and embodiments are described below in the section entitled “Detailed Description.”

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIG. 1 is a circuit diagram illustrating a conventional duty cycle correction circuit;

FIGS. 2 to 5 are block diagrams illustrating a duty cycle correction circuit according to various example embodiments;

FIG. 6 is a block diagram illustrating an example of a back-bias voltage adjustor included in the circuit shown in FIGS. 2 and 4;

FIG. 7 is a block diagram illustrating an example of a back-bias voltage adjustor included in the circuit shown in FIGS. 3 and 5

FIGS. 8 to 11 are circuit diagrams illustrating an example of a buffer and the back-bias voltage adjustors included in the circuit shown in FIGS. 2 to 5; and

FIG. 12 is a wave form of a clock signal and an output signal illustrating the operation of a duty cycle correction circuit configured in accordance with the embodiments of FIGS. 2-5.

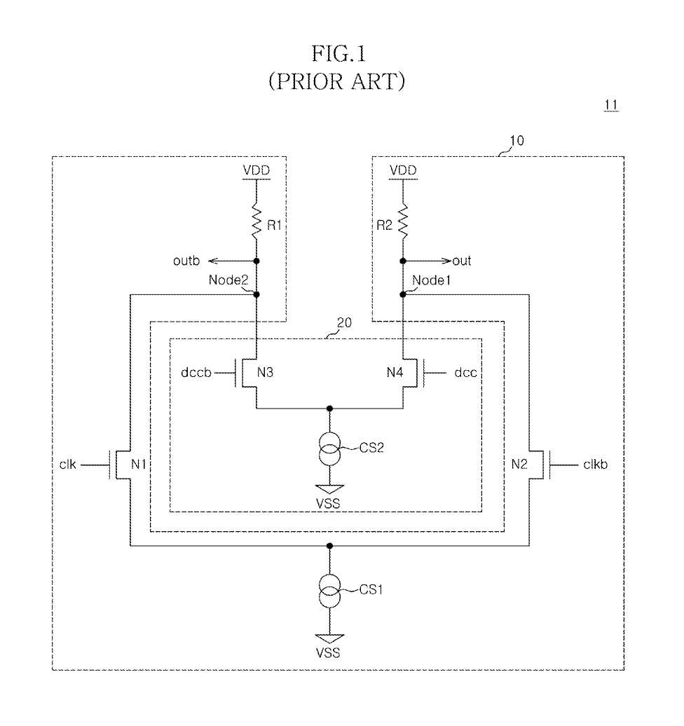

### DETAILED DESCRIPTION

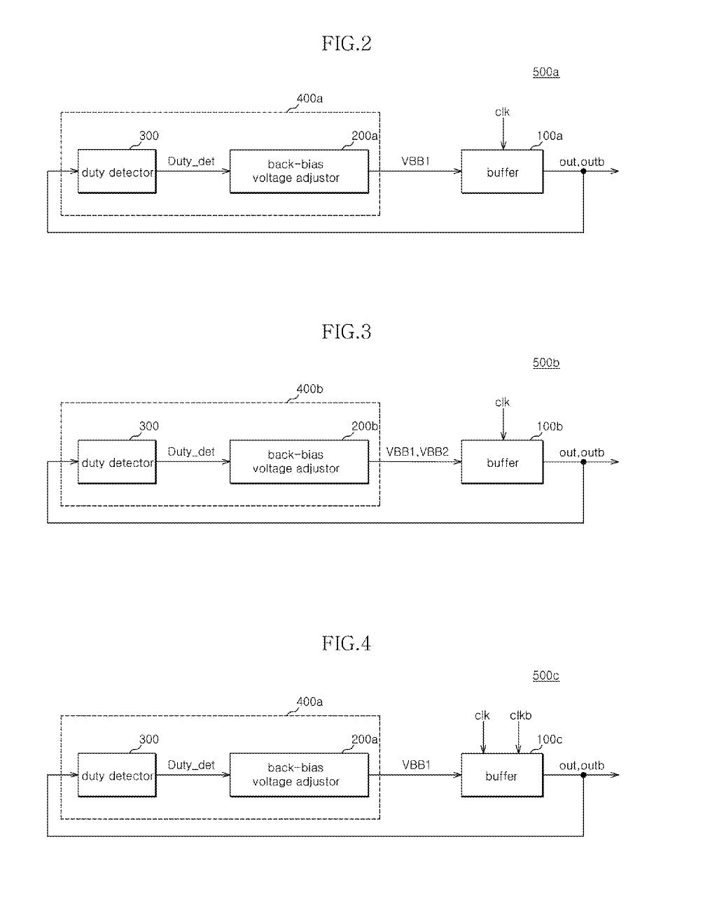

FIG. 2 is a diagram illustrating an example duty cycle correction circuit configured in accordance with one embodiment. Referring to FIG. 2, the duty cycle correction circuit 500a can include a back-bias voltage adjustor 200a and a buffer 100a.

The back-bias voltage adjustor 200a can be configured to generate a back-bias voltage VBB1 on which the duty cycle of an input clock signal ‘clk’ is reflected. The back-bias voltage adjustor 200a can be configured to receive output signals ‘out’ and ‘outb’ from the buffer 100a and then generate the back-bias voltage VBB1 in response to a duty detection signal ‘Duty_det’ on which the duty cycle of an input clock signal ‘clk’ is reflected.

The buffer 100a can be configured to receive the back-bias voltage VBB1, which is an output signal of the back-bias voltage adjustor 200a, and the clock signal ‘clk’ and then generate the output signals ‘out’ and ‘outb’ having a duty adjusted based on the back-bias voltage VBB1.

The duty cycle correction circuit 500a of FIG. 2 can further include a duty detector 300. The duty detector 300 can be configured to output the duty detection signal ‘Duty_det’ based on the duty cycle of the output signals ‘out’ and ‘outb’. The duty detector 300 can, e.g., be implemented by an analog duty detector or a digital duty detector. It can be preferable that the duty detector 300 be implemented by a digital duty detector in view of the reduction in size and the simplification of circuits that a digital duty detector provides relative to an analog duty detector. Accordingly, in the descriptions below, it will be assumed that duty detector 300 is implemented as a digital duty detector.

Here, the duty detector 300 forms a back-bias voltage supply circuit 400a, which outputs a duty-adjusted single voltage signal of the back-bias voltage VBB1, together with the back-bias voltage adjustor 200a.

In other embodiments, as shown in FIG. 3, a duty cycle correction circuit 500b can include a back-bias voltage supply circuit 400b configured to output a plurality of back-bias voltages VBB1 and VBB2 and a buffer 100b. Here, the back-bias voltage supply circuit 400b can include the duty detector 300 and a back-bias voltage adjustor 200b to output the plurality of the back-bias voltages. The buffer 100b can then be configured to generate the output signals ‘out’ and ‘outb’ having a duty cycle adjusted based on both back-bias signals VBB1 and VBB2.

Also, as shown in FIGS. 4 and 5, a duty cycle correction circuit 500c configured according to the embodiments described herein can comprise a buffer 100c that can be configured to receive an inverted clock signal ‘clkb’ as well as a click signal ‘clk’. The buffer 100c can be configured to generate the output signals ‘out’ and ‘outb’ based on the input clock signal ‘clk’ and the inverted clock signal ‘clkb’ and having the duty cycles adjusted based on back bias signal VBB1 (FIG. 4) or on back-bias signals VBB1 and VBB2 (FIG. 5).

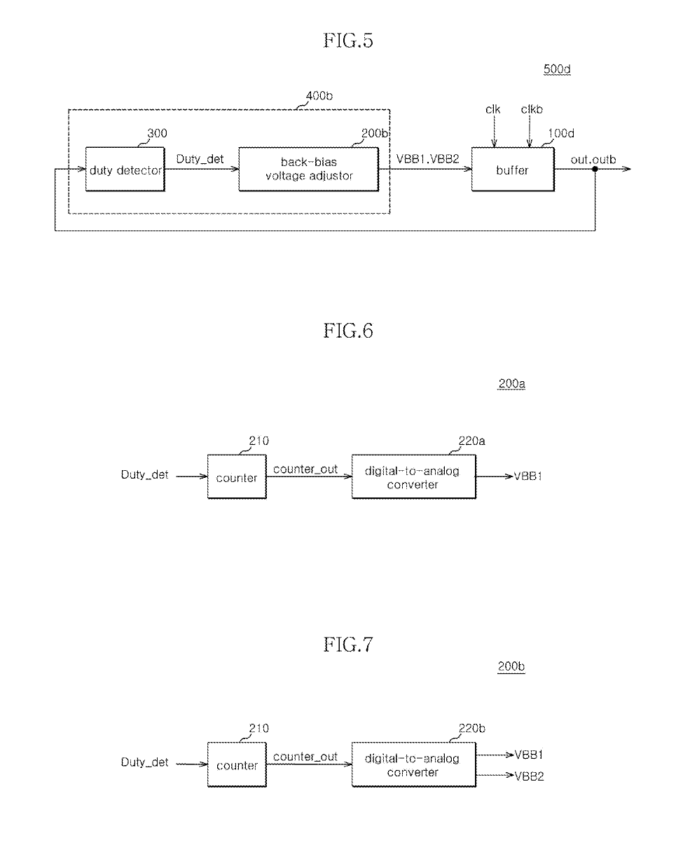

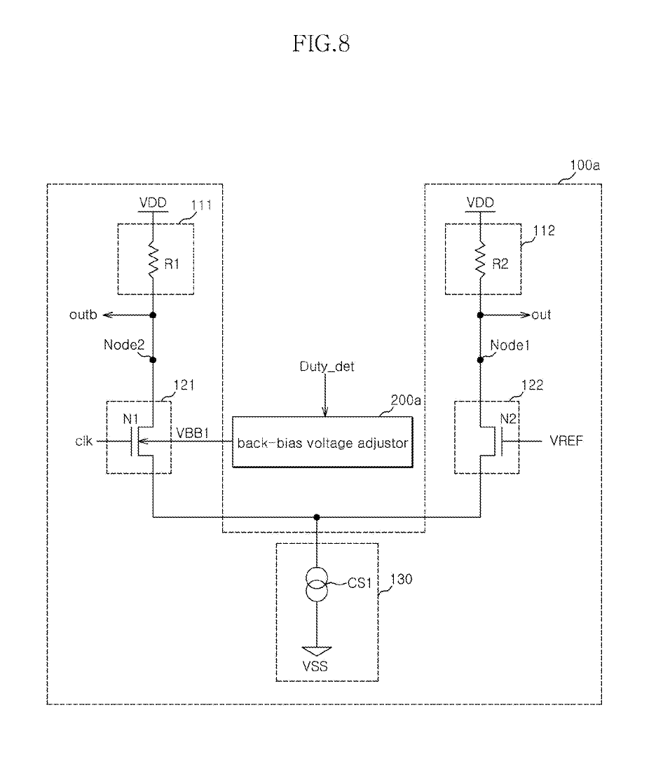

FIG. 6 is a diagram illustrating an example back-bias voltage adjuster 200a according to one embodiment. Referring to FIG. 6, the back-bias voltage adjustor 200a can be configured to generate the single bias voltage VBB1 and can include a counter 210 and a digital-to-analog converter 220a having a single output.

The counter 210 can be configured to increase or decrease a logic value of an output signal ‘counter_out’ of N bits (where N is a positive integer number) on a bit-by-bit basis. For example, the counter 210 can increase the logic value of the output signal ‘counter_out’ on a bit-by-bit basis when the duty detection signal ‘Duty_det’ is at a high level and decreases the logic value of the output signal ‘counter_out’ on a bit-by-bit basis when the duty detection signal ‘Duty_det’ is in a low level.

The digital-to-analog converter 220a can be configured to receive the output signal ‘counter_out’ of the counter 210 and convert the received signal into the back-bias voltage VBB1. The digital-to-analog converter 220a, the design of which is well-known, can be configured to convert a digital signal (‘counter_out’) into an analog signal (VBB1).

The digital-to-analog converter 220a can include a plurality of transistors (or switches) and a plurality of resistors, which are not shown in the drawings. That is, the digital-to-analog converter 220a can generate the back-bias voltage VBB1, by turning on and turning off the switches (transistors) based on the N-bit output signal (‘counter_out’) of the counter 210 and then controlling the number of resistors connected to a power supply voltage.

FIG. 7 is a diagram illustrating an example embodiment of a back-bias adjuster according to another embodiment. The back-bias voltage adjustor 200b can be configured to provide a plurality of back-bias voltages VBB1 and VBB2 and can include the counter 210 and a digital-to-analog converter 220b configured to provide a plurality of output signals as shown in FIG. 7.

Similar to the digital-to-analog converter 220a having a single output, the digital-to-analog converter 220b can include a plurality of transistors (or switches) and a plurality of resistors. The digital-to-analog converter 220b can provide the plurality of output signals VBB1 by turning on and off the switches (transistors) based on the N-bit output signal (‘counter_out’)of the counter 210 and by controlling the number of resistors connected to a power supply voltage.

The back-bias voltages VBB1 and VBB2 can be generated as first and second back-bias voltages respectively, and the additionally generated back-bias voltage VBB2 can be complementary to the back-bias voltage VBB1 in reference to a specific voltage. For example, assuming that the specific voltage is 3V, the first back-bias voltage VBB1 and the second back-bias voltage VBB2 can be set to be 2V and 4V, respectively. In another implementation, the first back-bias voltage VBB1 and the second back-bias voltage VBB2 can be set up to 1V and 5V, respectively, etc.

As shown in FIG. 8, the buffer 100a can include a first transistor N1 configured to receive the clock signal ‘clk’ and the first back-bias voltage VBB1 as a bulk voltage. Here, the first back-bias voltage VBB1 is provided by the back-bias voltage adjustor 200a.

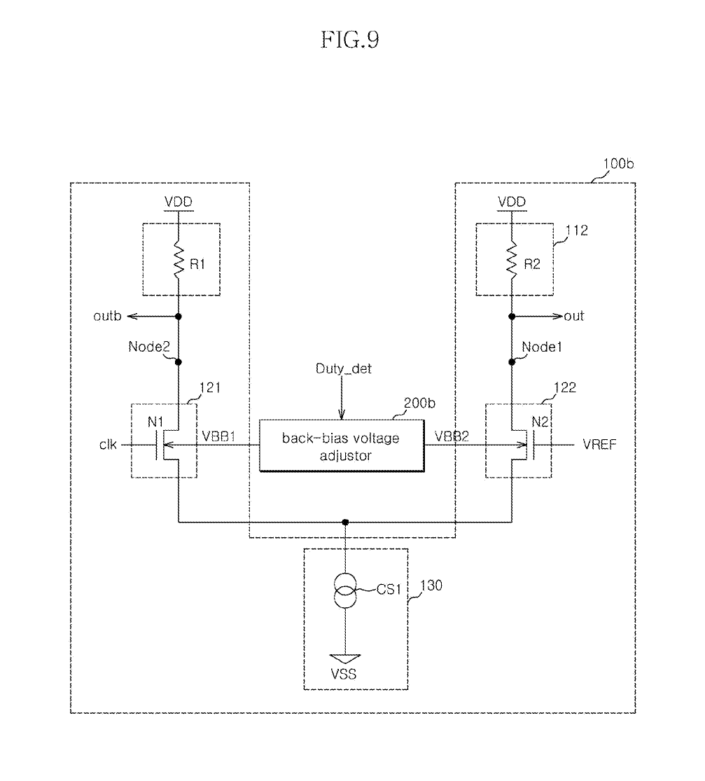

Also, as shown in FIG. 9, the buffer 100b can include a first transistor N1 configured to receive the clock signal ‘clk’ and the first back-bias voltage VBB1 as a bulk voltage. Additionally, the buffer 100b can include a second transistor N2 configured to receive a reference voltage VREF and the second back-bias voltage VBB2 as a bulk voltage. Here, the first and second back-bias voltages VBB1 and VBB2 are provided by the back-bias voltage adjustor 200b.

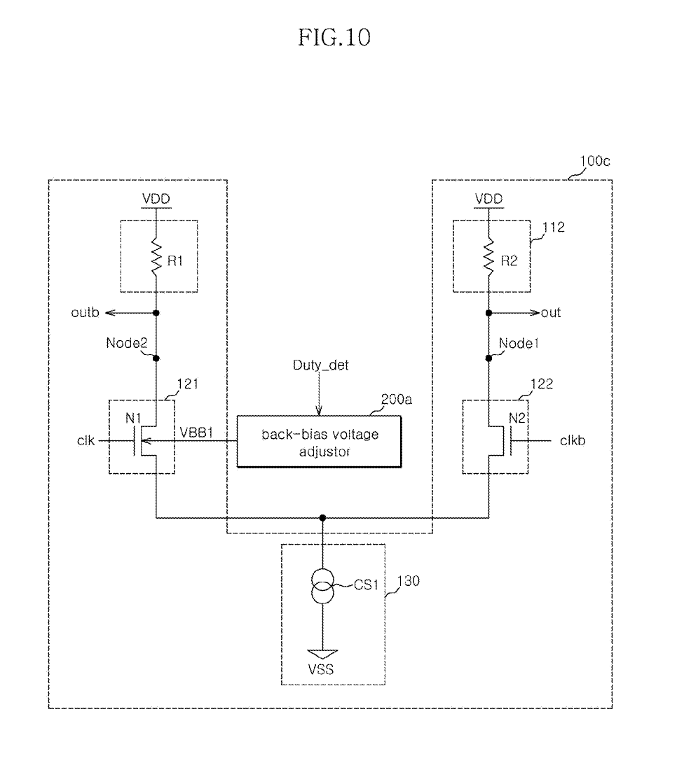

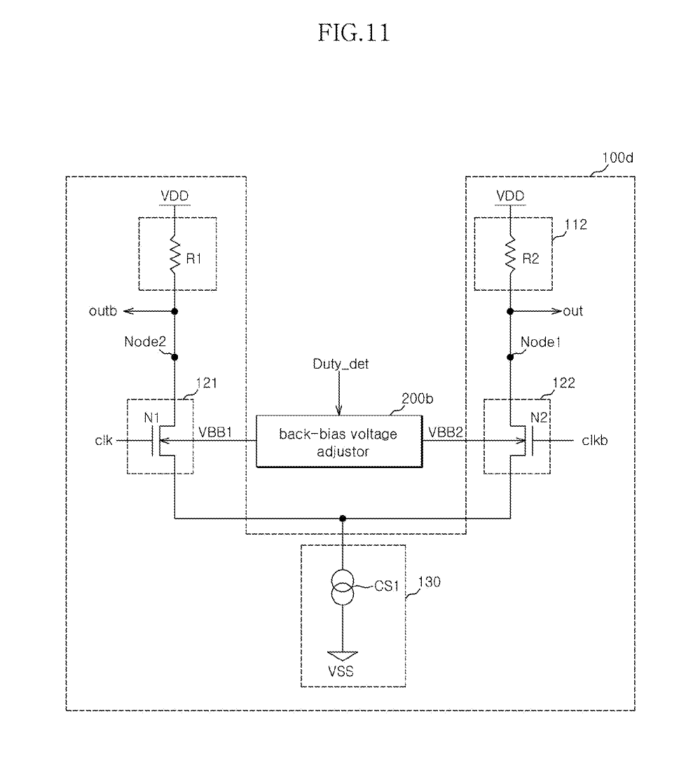

In case that the inverted clock signal ‘clkb’, which is generated by inverting the clock signal ‘clk’, is input into a buffer 100c as shown in FIG. 4, the inverted clock signal ‘clkb’ can be applied to a gate of the second transistor N2 as shown in FIGS. 10 and 11.

Each of the buffers 100a to 100d, as shown in FIGS. 8 to 11, can include load units 111 and 112, input units 121 and 122 comprising the first and second transistors N1 and N2, and a current source 130.

The load units 111 and 112 can be disposed between a terminal of the power supply voltage VDD and the input units 121 and 122, respectively. The input units 121 and 122 can be configured to receive current flowing into the input units 121 and 122 through loads 111 and 112, respectively, and then output the output signal ‘out’ and the inverted output signal ‘outb’, respectively. The load unit 111 including a resistance element R1 can be disposed between the terminal of the power supply voltage VDD and a first node Node1 through which the output signal ‘out’ is output and the load unit 112 including a resistance element R2 can be disposed between the terminal of the power supply voltage VDD and a second node Node2 through which the inverted output signal ‘outb’ is output.

Hereinafter, the load units 111 and 112 are referred to as first and second load units 111 and 112, respectively. The first and second load units 111 and 112 can include first and second resistors R1 and R2, respectively. The first resistor R1 is disposed between the terminal of the power supply voltage VDD and the second node Node2 and the second resistor R2 is disposed between the terminal of the power supply voltage VDD and the first node Node1. The inverted output signal outb is output from the second node Node2 and the output signal out is output from the first node Node1.

The input units 121 and 122 can include the first and second transistors N1 and N2 to selectively receive the first back-bias voltage VBB1 and/or the second back-bias voltage VBB2. As mentioned above, the first and second transistors N1 and N2 are driven by the clock signal ‘clk’ and the reference voltage VREF (or the inverted clock signal ‘clkb’) and can vary an amount of current flowing into the input units 121 and 122, respectively. The input units 121 and 122 can be disposed between the load unit 111 and 112, respectively, and the current source unit 130.

Hereinafter, the input units 121 and 122 are referred to as first and second input units 121 and 122. Depending on the implementations, the first input unit 121 and the second input unit 122 can include a first NMOS transistor N1 and a second NMOS transistor N2, respectively. The first NMOS transistor N1 can be configured to receive the first back-bias voltage VBB1 as the bulk voltage, and can have a gate to which the clock signal ‘clk’ is applied, a drain connected to the second node Node2, and a source connected to the current source CS1. The second NMOS transistor N2 can be configured to receive the second back-bias voltage VBB2 as the bulk voltage, and can have a gate to which the inverted clock signal ‘clkb’ is applied, a drain connected to the first node Node1, and a source connected to the current source CS1.

The current source unit 130 can include the current source CS1, which is disposed between the input units 121 and 122 and a terminal of a ground voltage VSS, in order to control the current flowing into the input units 121 and 122.

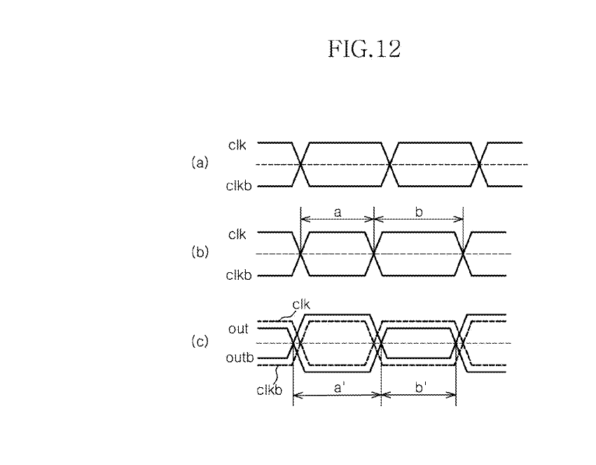

FIG. 12 is a wave form of the clock signal ‘clk’ and the output signal ‘out’ and illustrates the duty cycle correction that can occur in a duty cycle correction circuit configured in accordance with the embodiment described herein.

FIG. 12(a) is a timing chart illustrating a clock signal ‘clk’ with a 50% duty cycle and the corresponding inverted clock signal ‘clkb’. FIG. 12(b) is a timing chart illustrating a clock signal ‘clk’ with a duty cycle above 50% and the inverted clock signal ‘clkb’ thereof. By looking at periods (a) and (b) in FIG. 12(b) it can be seen that the clock signals illustrated therein do not have a duty cycle of 50% because the period (a) is shorter that the period (b).

FIG. 12(c) is a timing chart illustrating the output signal ‘out’ and the inverted output signal ‘outb’ of a duty cycle correction circuit according to the embodiments described herein. Here, the dotted line designates the clock signal ‘clk’ and the inverted clock signal ‘clkb’ of FIG. 12(b) before the duty correction and the solid line designates the duty-corrected output signal ‘out’ and the inverted output signal ‘outb’.

Referring to FIG. 12(c), the duty cycle of the clock signal ‘clk’ and the inverted clock signal ‘clkb’ of the dotted line is corrected, by decreasing a DC voltage level of the output signal ‘out’ and increasing a DC voltage level of the inverted output signal ‘outb’ through the output signals of the back-bias voltage adjustor. That is, a high pulse fraction (b) of the clock signal ‘clk’ is decreased to a high pulse fraction (b′) of the output signal ‘out’ and a low pulse fraction (a) of the clock signal ‘clk’ is increased to a low pulse fraction (a′) of the output signal ‘out’ so that the low pulse fraction (a′) of the output signal ‘out’ is the same as the high pulse fraction (b′) of the output signal ‘out’. As a result, the output signal ‘out’ and the inverted output signal ‘outb’ are generated with a 50% duty cycle.

Referring to FIGS. 2 to 12, the operation of a duty cycle correction circuit configured according to the embodiments described herein will be described in detail below.

In the following description, it will be assumed that the clock signal ‘clk’ and the inverted clock signal ‘clkb’ are input as input signals and the first and second back-bias voltages VBB1 and VBB2 are output as output signals.

In the case where the 50% duty cycle (FIG. 12(a)), each of the output signal ‘out’ and the inverted output signal ‘outb’ will also be provided with a 50% duty cycle.

In the case where the clock signal ‘clk’ does not have a 50% duty cycle (e.g., FIG. 12(b)), then the duty detection signal ‘Duty_det’ is in a logic high or low level according as the duty cycle of the output signal ‘out’. In other words, if the duty cycle of the output signal ‘out’ is above 50% then the duty detection signal ‘Duty_det’ will beat a logic high level. If the duty cycle of the output signal ‘out’ is less than 50%, then the duty detection signal ‘Duty_det’ will be at a logic low level. The back-bias voltage adjustor 200b complementarily increases or decreases the first and second back-bias voltages VBB1 and VBB2 according to the duty detection signal ‘Duty_det’, by using a specific voltage level as a reference voltage.

For example, in case that the duty cycle of the output signal out is 60%, the duty detection signal ‘Duty_det’ can be output in a logic high level. The counter 210 then increase the logic value of the N-bit output signal ‘counter_out’ by one bit. Accordingly, the digital-to-analog converter 220b complementarily increases or decreases the first and second back-bias voltages VBB1 and VBB2 according to the one-bit-increased output signal ‘counter_out’ of the counter 210.

As the second back-bias voltage VBB2 is increased, the threshold voltage of the second transistor N2 is decreased and a relatively large amount of current flows into the second transistor N2. Accordingly, the DC voltage level is decreased on the first node Node1.

Accordingly, when the clock signal ‘clk’ is input with 60% duty cycle (referring to FIG. 12(c)), then the pulse width of the output signal ‘out’ is properly decreased because the DC voltage level of the output signal ‘out’ is decreased. Further, due to the feedback of the output signal ‘out’, the duty cycle of the output signal ‘out’ is decreased below 60%, as explained further below.

The back-bias voltage adjustor 200b outputs the first and second back-bias voltages VBB1 and VBB2, which are adjusted according to the duty cycles of the output signal ‘out’ and the inverted output signal ‘outb’, and the buffer 100d generates a current difference through a voltage difference between the back-bias voltages VBB1 and VBB2 on both stages to which the clock signal ‘clk’ and the inverted clock signal ‘clkb’ are respectively applied and then makes a difference between both the stages in the DC voltage level. As a result, as shown in FIG. 12(c), the duty cycle of the output signal ‘out’ is corrected and the output signal ‘out’ and the inverted output signal ‘outb’ have a 50% duty cycle.

Furthermore, the duty-cycle-corrected output signal ‘out’ is fed back to the duty detector 300 and then detected again with the corrected duty cycle in order to output the duty detection signal ‘Duty_det’. At this time, in case the duty cycle of the corrected output signal ‘out’ is 55%, the duty cycle is not corrected completely even if the duty cycle is close to 50%. Accordingly, the duty detector 300 which receives the output signal ‘out’ with, e.g., the 55% duty cycle, outputs the duty detection signal ‘Duty_det’ in a logic high. The counter 210 then increase the logic value of the previous N-bit counter signal ‘counter_out’ by one bit and the digital-to-analog converter 220b makes the second back-bias voltage VBB2 higher than the first back-bias voltage VBB1. Accordingly, the threshold voltage of the second NMOS transistor N2 is decreased and the amount of current flowing into the second resistor R2 is increased. The DC voltage level on the first node Node1 is decreased further and the DC voltage level of the output signal ‘out’ is decreased. Further, the DC voltage level on the inverted output signal ‘outb’ is increased. This iterative process should achiveve the desired 50% duty cycle using a single current source CS1, which should reduce current consumption.

It will be apparent that corrections of more or less than 5% per iteration can be achieved with the embodiments described herein.

The embodiments described herein can be applied to any semiconductor integrated circuit using a clock signal. Particularly, the embodiments described herein can be used in various semiconductor fields such as CPUs (Central Processing Unit) and ASICs (Application Specific Integrated Circuit).

While certain embodiments have been described above, it will be understood that the embodiments described are by way of example only. Accordingly, the systems and methods described herein should not be limited based on the described embodiments. Rather, the systems and methods described herein should only be limited in light of the claims that follow when taken in conjunction with the above description and accompanying drawings.

What is claimed is:

1. A duty cycle correction circuit comprising:
a back-bias voltage supply circuit configured to receive an output signal and to generate a back-bias voltage, wherein a duty cycle of an input clock signal is reflected on the back-bias voltage; and
a buffer configured to receive the input clock signal and the back-bias voltage, to adjust the duty cycle of the input clock signal in response to the back-bias voltage, and to output the output signal based on the adjusted input clock signal.

2. The duty cycle correction circuit of claim 1, wherein the buffer is configured to generate the output signal by adjusting the DC voltage level of the input clock signal in response to the back-bias voltage.

3. The duty cycle correction circuit of claim 1, wherein the back-bias voltage causes the DC voltage level of the input clock signal to be decreased, when the duty cycle of the input clock signal is greater than 50%, and wherein the back-bias voltage causes the DC voltage level of the input clock signal to be increased when the duty cycle of the input clock signal is less than 50%.

4. The duty cycle correction circuit of claim 2, wherein the back-bias voltage supply circuit includes:
a duty detector circuit configured to receive the output signal, determine the duty cycle of the output signal, and output a duty detection signal; and
a back-bias voltage adjustor configured to generate the back-bias voltage in response to the duty detection signal.

5. The duty cycle correction circuit of claim 4, wherein the back-bias voltage adjustor includes:
a counter configured to generate a count signal according to the duty detection signal; and
a digital-to-analog converter configured to convert the count signal into the back-bias voltage.

6. The duty cycle correction circuit of claim 1, wherein the buffer includes a first input unit configured to receive the input clock and the back-bias voltage.

7. The duty cycle correction circuit of claim 6, wherein the buffer includes a second input unit configured to receive a reference voltage.

8. The duty cycle correction circuit of claim 7, wherein the first and second input units each comprise a transistor, and wherein the back-bias voltage is used as a bulk voltage for the transistor included in the first input unit.

9. The duty cycle correction circuit of claim 7, wherein the buffer further comprises:
a current source unit coupled with the first input unit, and wherein the current source unit is further configured to provide a current flowing into the first input unit, and wherein the first input unit is further configured to vary an amount of current flowing through the first input unit according to the back-bias voltage;
a power supply voltage terminal; and
a first load unit coupled with the power supply voltage terminal and the first input unit, the load unit configured to output the output signal, the DC voltage level of which is based on an amount of current flowing through the first input unit.

10. The duty cycle correction circuit of claim 1, wherein the back-bias voltage supply circuit is further configured to generate two back-bias voltages, and wherein the buffer includes:
a first input unit configured to receive the input clock and a first of the two back-bias voltages; and
a second input unit configured to receive a reference voltage and a second of the two back-bias voltages.

11. The duty cycle correction circuit of claim 10, wherein the first and second input units each comprise a transistor, and wherein the first of the two back-bias voltages is used as a bulk voltage for the transistor included in the first input unit and the second of the two back-bias voltages is used as a bulk voltage for the transistor included in the second input unit.

12. The duty cycle correction circuit of claim 10, wherein the buffer further comprises:
a current source unit coupled with the first input unit, and wherein the current source unit is further configured to provide a current flowing into the first input unit, and wherein the first input unit is further configured to vary an amount of current flowing through the first input unit according to the back-bias voltage;
a power supply voltage terminal; and
a first load unit coupled with the power supply voltage terminal and the first input unit, the load unit configured to output the output signal, the DC voltage level of which is based on an amount of current flowing through the first input unit.

13. The duty cycle correction circuit of claim 12, wherein the buffer is further configured to generate the output signal and an inverted output signal, the inverted output signal being the inverse of the output signal, and wherein the buffer further comprises a second load unit coupled with the power supply voltage terminal and the second input unit, the second load unit configured to output the inverted output signal, the DC voltage level of which is based on an amount of current flowing through the second input unit.

14. The duty cycle correction circuit of claim 7, wherein the second input buffer is configured to receive an inverted input clock signal instead of the reference voltage.

15. The duty cycle correction circuit of claim 10, wherein the second input buffer is configured to receive an inverted input clock signal instead of the reference voltage.

16. The duty cycle correction circuit of claim 1, wherein the buffer includes a differential amplifier.

17. A method for correcting a duty cycle in a duty cycle correction circuit, the method comprising:
outputting a duty detection signal by detecting a duty cycle of an output signal;
generating back-bias voltages in response to the duty detection signal; and
receiving an input clock signal and generating the output signal by adjusting the duty cycle of the input clock signal according to the back-bias voltages.

18. The method of claim 17, wherein the adjusting of the duty cycle of the input clock signal adjusts a difference in an amount of DC current between nodes through which the output signal and an inverted output signal are output, according to the back-bias voltages.

19. The method of claim 17, wherein the generating of the back-bias voltages includes:
increasing or decreasing a count signal from a counter on a bit-by-bit basis according to the duty detection signal; and
generating the back-bias voltages by converting the count signal into analog signals.

20. A buffer for use in a duty cycle correction circuit, the buffer comprising a first input unit configured to receive an input clock and a first back-bias voltage, the duty cycle of the input clock signal being reflected on the first back-bias voltage;
a second input unit configured to receive a reference voltage;
a current source unit coupled with the first input unit, and wherein the current source unit is further configured to provide a current flowing into the first input unit, and wherein the first input unit is further configured to vary an amount of current flowing through the first input unit according to the first back-bias voltage;
a power supply voltage terminal; and
a first load unit coupled with the power supply voltage terminal and the first input unit, the load unit configured to output an output signal, the DC voltage level of which is based on an amount of current flowing through the first input unit.

21. The duty cycle correction circuit of claim 20, wherein the buffer further comprises a second input unit configured to receive a reference voltage and a second back-bias voltage.

22. The duty cycle correction circuit of claim 21, wherein the buffer is further configured to generate the output signal and an inverted output signal, the inverted output signal being the inverse of the output signal, and wherein the buffer further comprises a second load unit coupled with the power supply voltage terminal and the second input unit, the second load unit configured to output the inverted output signal, the DC voltage level of which is based on an amount of current flowing through the second input unit.

23. The duty cycle correction circuit of claim 22, wherein the first and second input units each comprise a transistor, and wherein the first back-bias voltage is used as a bulk voltage for the transistor included in the first input unit and the second back-bias voltage is used as a bulk voltage for the transistor included in the second input unit.

24. The duty cycle correction circuit of claim 21, wherein the second input buffer is configured to receive an inverted input clock signal instead of the reference voltage.

25. The duty cycle correction circuit of claim 20, wherein the buffer includes a differential amplifier.
